(19) United States
(12) Patent Application Publication
(10) Pub. No.: US 2021/0020620 A1
(43) Pub. Date: Jan. 21, 2021

(54) OPTOELECTRONIC COMPONENT AND METHOD FOR PRODUCING SAME

(71) Applicant: Osram OLED GmbH, Regensburg (DE)

(72) Inventors: Britta GOEOETZ, Regensburg (DE); Frank SINGER, Regenstauf (DE)

(21) Appl. No.: 16/979,887

(22) PCT Filed: Mar. 13, 2019
(86) PCT No.: PCT/EP2019/056215

§ 371 Date: Sep. 11, 2020

(30) Foreign Application Priority Data
Mar. 14, 2018 (DE) 10 2018 105 884.5

(51) Int. Cl. H01L 25/16; H01L 25/075; H01L 33/62; H01L 33/50; F21S 41/141

(52) U.S. Cl. CPC H01L 25/167; H01L 25/0753; H01L 33/62; F21Y 2115/10; F21S 41/141; H01L 33/504; H01L 2933/0041; H01L 33/508

(57) ABSTRACT

Optoelectronic components are described that may include a plurality of light-emitting regions arranged on a carrier substrate. Microwires may project relative to a main surface of the carrier substrate. A plurality of microwires may be arranged between each pair of adjacent light-emitting regions. The light-emitting regions may each be surrounded by rows of microwires.

### CROSS-REFERENCE TO RELATED APPLICATIONS

The present application is a national stage entry according to 35 U.S.C. § 371 of PCT application No.: PCT/EP2019/056215 filed on Mar. 13, 2019; which claims priority to German Patent Application Serial No.: 10 2018 105 884.5 filed on Mar. 14, 2018; all of which are incorporated herein by reference in their entirety and for all purposes.

### TECHNICAL FIELD

An optoelectronic component with microwires that project relative to a main surface of a carrier substrate is disclosed. In addition, a method for producing such a component is specified.

### BACKGROUND

A light-emitting diode (LED) is a light-emitting device based on semiconductor materials. Typically, an LED comprises a pn-junction. When electrons and holes recombine with each other in the area of the pn-junction, for example because an appropriate voltage is applied, electromagnetic radiation is generated. LEDs are designed for a wide range of applications including display devices, lighting devices, automotive lighting, projectors and others. For example, arrangements of LEDs or light-emitting regions, each with a plurality of LEDs or light-emitting regions, are widely used for these purposes.

### SUMMARY

The object of various embodiments is to specify an improved optoelectronic component having a plurality of light-emitting regions and a method for producing the same.

An optoelectronic component comprises a plurality of light-emitting regions arranged on a carrier substrate, in addition to microwires that project relative to a main surface of the carrier substrate. The microwires are each arranged between individual light-emitting regions. A plurality of microwires is arranged between each pair of adjacent light-emitting regions. For example, the microwires may contain a metallic material.

The diameter of the microwires can range from 600 nm to 1500 nm. The spacing between the microwires can range from 0.1 μm to μm. The spacing of the microwires can be selected independently of the diameter of the microwires.

According to embodiments, the microwires are arranged along at least one line, forming a row of microwires. For example, the light-emitting regions can each be surrounded by rows of microwires. This can reduce crosstalk between adjacent light-emitting regions.

In addition, the optoelectronic component may also have a converter-containing casting compound over at least one of the light-emitting regions. The converter-containing casting compound can be directly adjacent to the row of microwires that surrounds the light-emitting region. For example, due to the surface energy of the microwires and the viscosity of the casting compound, a skin can be formed between adjacent microwires, through which any lateral outflow can be prevented. The converter-containing casting compound can therefore be bounded by the microwire row.

According to further embodiments, different converter-containing casting compounds may be present over adjacent light-emitting regions. Due to the presence of the microwires, the different converter-containing casting compounds can be effectively separated from one another. As a result, it is possible to provide different converter-containing casting compounds at a small distance above an optoelectronic component.

For example, a space can be arranged between each of the microwire rows of adjacent light-emitting regions. The intermediate space can be filled with optically isolating material. This can improve the optical isolation between adjacent light-emitting regions.

According to other embodiments, an arrangement of further microwires may be present in the intermediate space. This also improves the optical isolation between adjacent light-emitting regions.

Alternatively, exactly one row of microwires can be arranged between adjacent light-emitting regions. This enables a more compact design of the optoelectronic component to be achieved.

In addition, a casting material arranged along the microwire row may be provided. In this way, for example, adjacent light-emitting regions can be separated from each other more easily with reduced space requirements.

For example, the light-emitting regions may include optoelectronic semiconductor chips.

The microwires can be insulated from electrical components of the optoelectronic component. More specifically, they can be insulated from semiconductor layers, for example. Accordingly, for example, they can fulfill a mechanical or optical function rather than an electrical function.

A method for producing an optoelectronic component comprises the arrangement of a plurality of light-emitting regions on a carrier substrate and the formation of a plurality of microwires which are each arranged between individual light-emitting regions. The microwires protrude at right angles relative to a main surface of the carrier substrate. A plurality of microwires is arranged between each pair of adjacent light-emitting regions.

The microwires can each have a diameter from 600 nm to 1500 nm. The spacing between the microwires can range from 0.1 μm to 15 μm. The spacing of the microwires can be selected independently of the diameter of the microwires.

For example, the microwires can be formed by electroplating. Such a method can be carried out using a structured plastic film.

For example, the microwires can be arranged along lines and form a row of microwires. The method may also include the application of a converter-containing casting compound over one of the light-emitting regions. The converter-containing casting compound can be adjacent to the microwire row that surrounds the light-emitting region.

An electrical device may contain the optoelectronic component described. The electrical device may be a vehicle headlamp or a general lighting device.

### BRIEF DESCRIPTION OF THE DRAWINGS

The accompanying drawings are intended to allow the understanding of the non-limiting embodiments. The elements and structures shown in the drawings are not necessarily shown true to scale relative to each other. The same reference signs refer to identical or corresponding elements and structures.

FIGS. 1A to 1C are schematic views of optoelectronic components in accordance with embodiments.

FIGS. 2A to 2C are cross-sectional views of a workpiece during the production of an optoelectronic component in accordance with embodiments.

FIG. 2D shows a cross-sectional view of an optoelectronic component according to embodiments.

FIGS. 2E and 2F show plan views of parts of an optical component in accordance with embodiments.

FIGS. 3A and 3B are cross-sectional views of optoelectronic components in accordance with further embodiments.

FIGS. 4A and 4B are schematic plan views of regions of optoelectronic components in accordance with embodiments.

FIGS. 5A and 5B are cross-sectional views of a workpiece for producing an optoelectronic component in accordance with further embodiments.

FIG. 5C is a schematic plan view of a part of an optoelectronic component in accordance with further embodiments.

FIG. 6A shows a schematic plan view of a part of an optoelectronic component in accordance with embodiments.

FIG. 6B shows a cross-sectional view through an optoelectronic component in accordance with embodiments.

FIG. 7A shows a cross-sectional view to illustrate a method step for producing an optoelectronic component.

FIG. 7B shows a perspective view of a film for carrying out a method.

FIG. 8 summarizes a method according to an exemplary embodiment.

FIGS. 9A and 9B are cross-sectional views of a workpiece for producing optoelectronic components in accordance with further embodiments.

FIG. 10 shows an electrical device according to embodiments.

### DETAILED DESCRIPTION

In the following detailed description, reference is made to the accompanying drawings, which form part of the disclosure and in which specific exemplary embodiments are shown for illustrative purposes. In this context, a directional terminology such as “top”, “bottom”, “front side”, “rear side”, “over”, “on”, “in front”, “behind”, “forwards”, “backwards” etc. is relative to the orientation of the figures just described. Since the components of the exemplary embodiments can be positioned in different orientations, the directional terminology is only used for explanation and is not restrictive in any way.

The description of the exemplary embodiments is not restrictive, as other exemplary embodiments also exist and structural or logical changes can be made without any deviation from the scope defined by the patent claims. In particular, elements of exemplary embodiments described below may be combined with elements of other exemplary embodiments described, unless the context indicates otherwise.

The terms “wafer”, “substrate” or “semiconductor substrate” used in the following description may comprise any semiconductor-based structure that has a semiconductor surface. Wafer and structure are to be understood in such a way that they include doped and undoped semiconductors, epitaxial semiconductor layers, supported by a base semiconductor substrate, and other semiconductor structures. For example, a layer of a first semiconductor material can be grown on a growth substrate made from a second semiconductor material. Depending on the intended use, the semiconductor may be based on a direct or indirect semiconductor material. Examples of semiconductor materials particularly suitable for generating electromagnetic radiation include, in particular, nitride semiconductor compounds, which can be used to produce ultraviolet, blue or longer-wavelength light, for example, such as GaN, InGaN, AlN, AlGaN, AlGaInN, or phosphide semiconductor compounds, which can be used to produce green or longer-wavelength light, such as GaAsP, AlGaInP, GaP, AlGaP, and other semiconductor materials such as AlGaAs, SiC, ZnSe, GaAs, ZnO, Ga₂O₃, diamond, hexagonal BN and combinations of the above materials. The stoichiometric ratio of the compound semiconductors with more than two elements can vary. Other examples of semiconductor materials can include silicon, silicon-germanium and germanium. In the context of this description, the term “semiconductor” also includes organic semiconductor materials.

The terms “lateral” and “horizontal” as used in this description are intended to describe an orientation or alignment that runs essentially parallel to a first surface of a semiconductor substrate or semiconductor body. This can be, for example, the surface of a wafer, a die or a chip.

The term “vertical” as used in this description is intended to describe an orientation that runs essentially perpendicular to the first surface of the semiconductor substrate or semiconductor body.

Where the terms “have”, “contain”, “comprise”, “possess” and the like are used, these are open terms which indicate the presence of the said elements or features but do not exclude the presence of further elements or features. The indefinite articles and the definite articles include both the plural and the singular, unless the context clearly indicates otherwise.

In the context of this description, the term “electrically connected” means a low-resistance electrical connection between the connected elements. The electrically connected elements do not necessarily have to be directly connected to each other. Other elements can be arranged between electrically connected elements.

Typically, the wavelength of electromagnetic radiation emitted by an LED chip can be converted using a converter material containing a fluorescent substance or phosphor. For example, white light can be generated by a combination of an LED chip that emits blue light with a suitable fluorescent. For example, the fluorescent may be a yellow fluorescent which, when excited by the light of the blue LED chip, is suitable for emitting yellow light. The fluorescent can, for example, absorb part of the electromagnetic radiation emitted by the LED chip. The combination of blue and yellow light is perceived as white light. By adding other fluorescent substances which are suitable for emitting light of another wavelength, for example red, the color temperature, the color quality, the luminous efficiency or other properties of the generated light can be modified, for example. In general, by using a suitable converter the light source can be tailored to the respective requirements. According to further designs, white light can be produced by a combination containing a blue LED chip and a green fluorescent. It goes without saying that a converter material can comprise a plurality of different fluorescents, each of which emits a different wavelength.

Examples of fluorescent substances include metal oxides, metal halides, metal sulfides, metal nitrides and others. These compounds may also contain additives that cause specific wavelengths to be emitted. For example, the additives can include rare earth materials. An example of a yellow fluorescent is YAG:Ce³⁺ (Yttrium Aluminum Garnet (Y₃Al₅O₁₂) activated with cerium) or (Sr_{1.7}Ba_{0.2}Eu_{0.1})SiO₄. Other fluorescents can be based on MSiO₄:EU²⁺, where M can be Ca, Sr or Ba. By selecting the cations with an appropriate concentration, a desired conversion wavelength can be selected. Many other examples of suitable luminescent substances are known.

According to applications, the fluorescent material, for example a fluorescent powder, can be embedded in a suitable matrix material. For example, the matrix material may contain a resin or polymer composition, such as a silicone or an epoxy resin. The size of the fluorescent particles can be in a micron or nanometer range, for example.

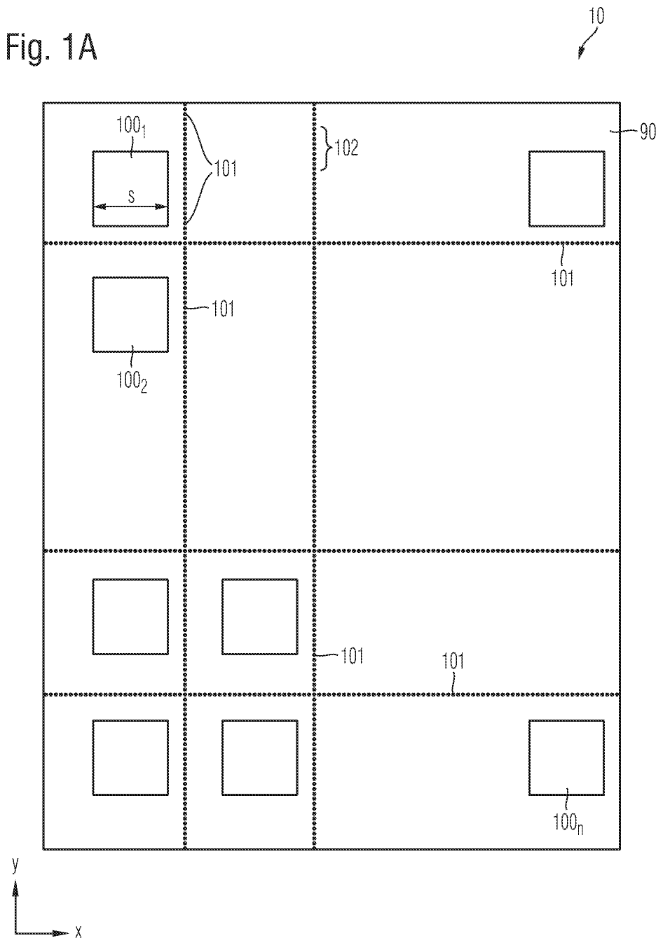

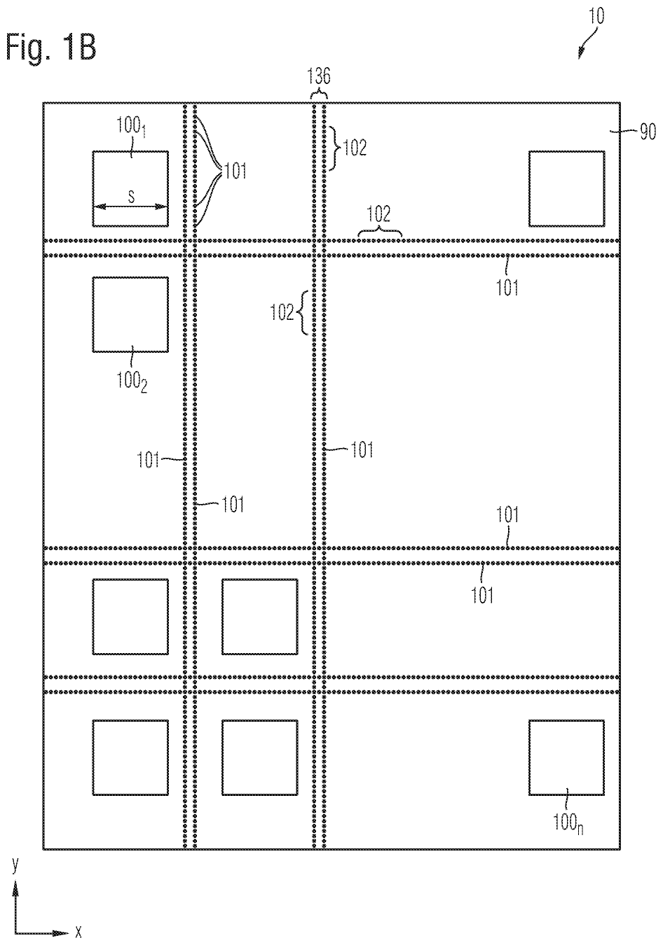

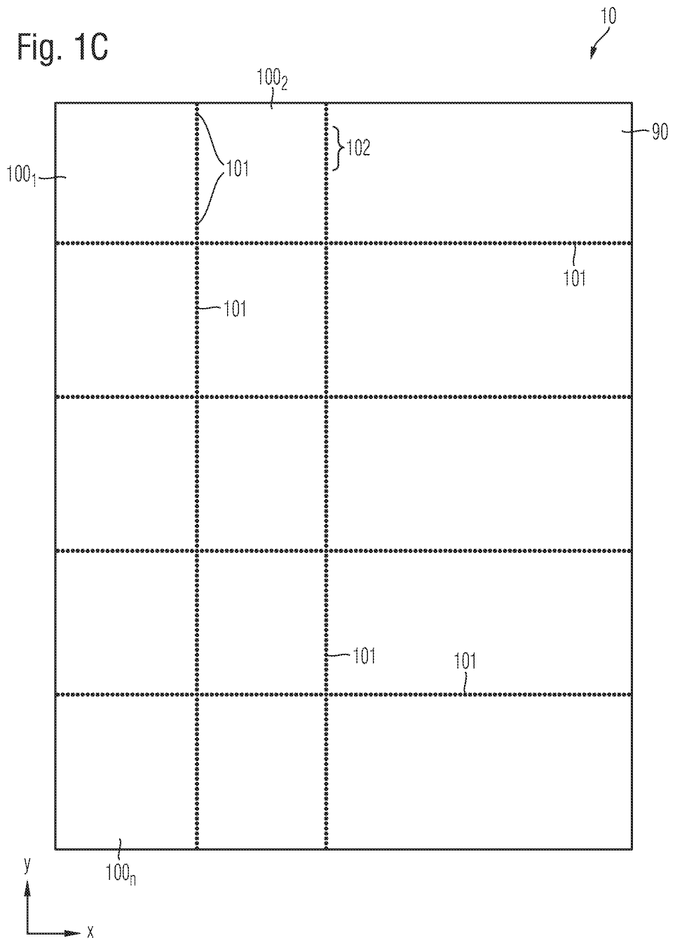

FIG. 1A shows a plan view of an example of an optoelectronic component 10. The optoelectronic component 10 comprises a plurality of light-emitting regions 100₁, 100₂, . . . , 100ₙ. The optoelectronic component 10 also has protruding microwires 101, which are arranged between individual light-emitting regions 100₁, . . . , 100ₙ. The microwires protrude from a main surface 91 of a carrier substrate 90. For example, they can extend perpendicular or approximately perpendicular to a main surface or light-emitting surface of the light-emitting regions.

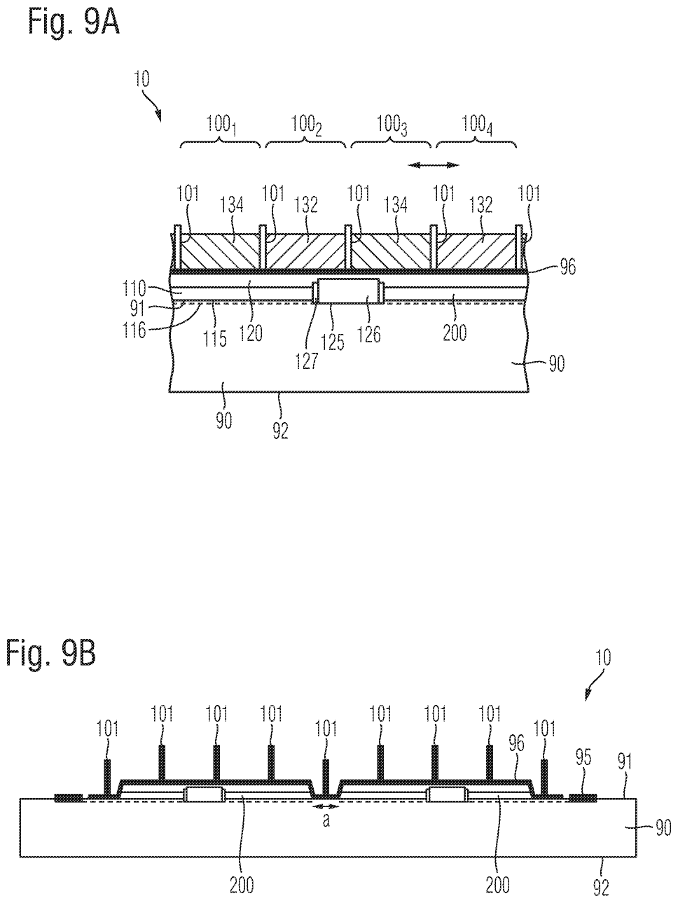

For example, the individual light-emitting regions 100 are implemented by individual optoelectronic semiconductor chips. For example, these can each have a different or identical structure. However, it is also possible that an optoelectronic semiconductor chip is assigned multiple light-emitting regions or pixels, which are separated from each other by the microwires. This is illustrated in more detail in FIGS. 1C and 9 below.

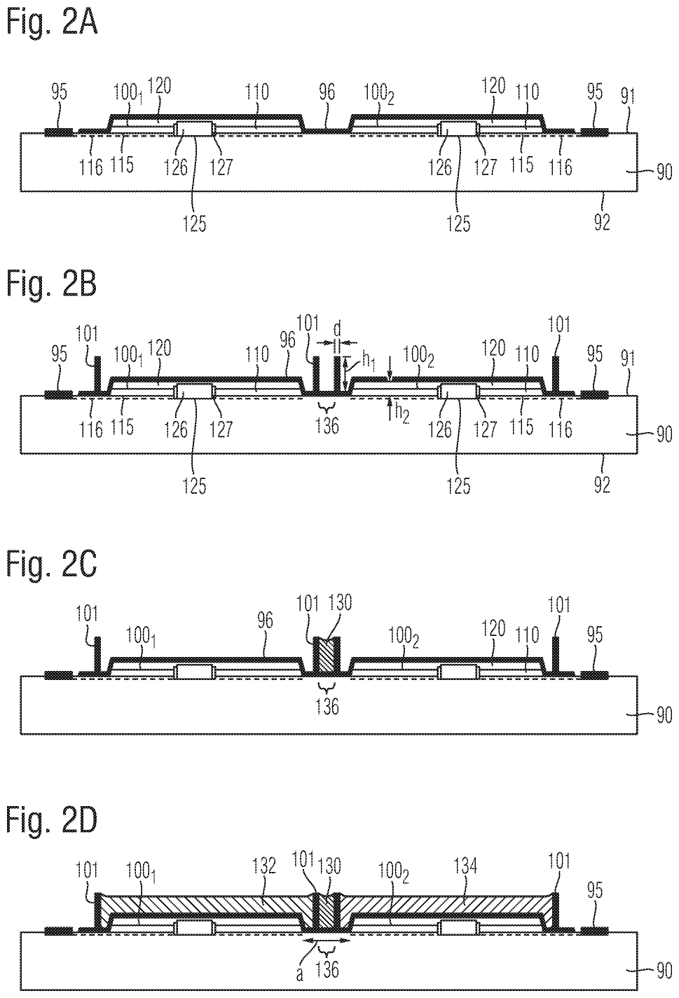

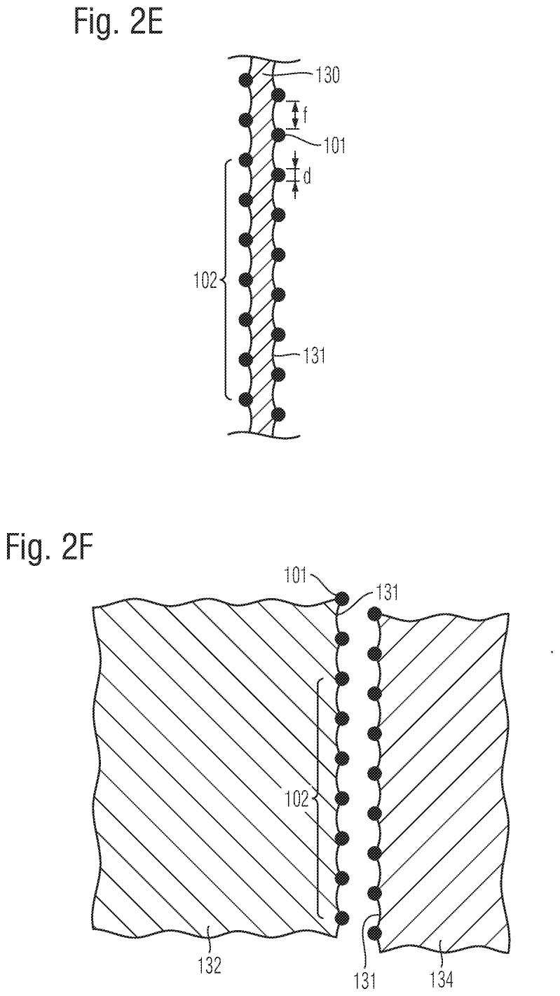

An example of a structure of the semiconductor chips will be described with reference to FIG. 2A. For example, the carrier substrate 90 can be an insulating substrate or a semiconductor substrate. For example, the carrier substrate 90 can be a silicon substrate in which further circuit components are arranged, in particular for contacting or controlling the individual light-emitting regions 100. The carrier substrate 90 can also be designed as an intermediate substrate, which is arranged on another substrate that contains components for activating the individual light-emitting regions 100, for example. In this case, the intermediate substrate can comprise electrical connecting leads for connecting the light-emitting regions to components of the control circuits.

The light-emitting regions can be arranged in any configuration. For example, they can be arranged in rows and columns as shown in FIG. 1A. However, they can also realize alternative arrangement patterns, depending on the application. Also, the shape of the light-emitting regions does not necessarily have to be rectangular or square. Depending on the design, the individual light-emitting regions can also be any other shape, for example round, oval, triangular or polygonal. The light-emitting regions 100 can be implemented by optoelectronic semiconductor chips. The optoelectronic semiconductor chips can also be based on organic semiconductor materials. In addition, other types of light generation can be used other than recombination of holes and electrons in the semiconductor material.

As illustrated in FIG. 1A, microwires 101 protruding from a main surface 91 of the carrier substrate 90 are arranged between individual light-emitting regions 100. A plurality of microwires 101 is arranged between each pair of adjacent light-emitting regions 100. A plurality of microwires 101 is arranged to form a microwire arrangement 102. For example, a microwire arrangement 102 can be designed in the form of a line. A microwire arrangement in the form of a line can represent a straight line, for example. Alternatively, however, a microwire arrangement 102 in the form of a line can represent a wide range of other geometric shapes, such as a curved line. According to the embodiment of FIG. 1A, microwire arrangements 102 are designed in such a way that they represent a kind of dividing line between adjacent light-emitting regions. In other words, inside the arrangement of light-emitting regions, a single light-emitting region is completely surrounded by microwire arrangements 102. For example, the microwire arrangements can be lines that run parallel to the X and Y directions, thus separating the light-emitting regions from one another in the X and Y directions.

For example, the light-emitting regions 100 can have a width s of more than 1 μm, for example even more than 10 μm. The width s can be less than 200 μm. For example, the width s can denote a dimension in the X or Y direction.

The diameter of the microwires can range from 600 nm to 1500 nm. The spacing between the microwires can range from 0.1 μm to 15 μm. The spacing of the microwires can be selected independently of the diameter of the microwires.

According to the embodiment of FIG. 1A, an arrangement of microwires 102 or a microwire row is provided between adjacent light-emitting regions.

According to the embodiment of FIG. 1B, two microwire arrangements 102 or microwire rows are provided between two adjacent light-emitting regions 100. For example, the two microwire arrangements between adjacent light-emitting regions can run parallel to each other. However, it is obvious that, particularly in the case of a different arrangement of light-emitting regions or a different geometric form of the microwire arrangement, the neighboring microwire arrangements do not have to run parallel to each other.

FIG. 1C shows a plan view of an optoelectronic component 10 according to further embodiments. In the optoelectronic components shown in FIG. 1C, a plurality of light-emitting regions 100₂, 100₂, . . . 100ₙ are assigned to a single semiconductor chip (not shown in FIG. 1C). It is also possible that more than one light-emitting region is assigned to more than one semiconductor chip. In this case, the number of light-emitting regions, or pixels, is greater than the number of semiconductor chips. Unlike as shown in FIG. 1A, the microwire rows 102 here do not extend exclusively between neighboring semiconductor chips, but can also run across the semiconductor chips so that the emitting surface of the semiconductor chips is divided by the microwire rows 102. This will be explained in more detail below with reference to FIGS. 9A and 9B. The additional details of the optoelectronic component 10 are similar to those shown in FIGS. 1A and 1B. Here, also, a plurality of microwires is arranged between adjacent light-emitting regions.

FIG. 2A shows a cross-sectional view through components of an optoelectronic component in the production of the optoelectronic component according to embodiments. Light-emitting regions 100₁, 100₂ are arranged on the first main surface 91 of a suitable carrier substrate 90. For example, the carrier substrate 90 can be insulating or have an insulating layer in the region of the first main surface 91. Light-emitting regions 100₁, 100₂ can be implemented, for example, by optoelectronic semiconductor chips.

For example, the optoelectronic semiconductor chips can have a first semiconductor layer 110 and a second semiconductor layer 120, stacked vertically on top of one another. For example, the first semiconductor layer 110 can be of the first conductivity type, e.g. n-type, and the second semiconductor layer 120 is of a second conductivity type, for example p-type. For example, the first semiconductor layer 110 can be arranged adjacent to the first main surface 91 and can be connected in an electrically conductive manner to a contact element 95 via a first contact region 115 and an electrical connection 116. For example, the second semiconductor layer can be arranged on the side facing away from the carrier substrate 90 and be connected in an electrically conductive manner to a second contact region 125 by means of a via-contact 126. An insulating material 127 can isolate the via-contact 126 from adjacent semiconductor material.

For example, the second contact region 125 can be suitably connected, for example, in front of or behind the drawing plane shown, to another contact region (not shown) in an electrically conductive manner. For example, the first and second semiconductor layer 110, 120 may have been produced by epitaxial growth on a growth substrate (not shown). Of course, the optoelectronic semiconductor chips can be implemented in a different manner. In particular, the electrical contacts may be designed differently.

According to embodiments, the first and second semiconductor layers 110, 120 may have been detached from the growth substrate by a suitable process and subsequently applied to the carrier substrate 90. According to other embodiments, other layers in addition to the layers shown or the growth substrate may be present. In this case, for example, the optoelectronic semiconductor chip comprises both the growth substrate and first and second semiconductor layers 110, 120. In addition, the light-emitting region 100₁, 100₂ can be implemented by optoelectronic semiconductor chips of any other kind and also in other ways. The light-emitting regions 100₁, 100₂ can also be covered with a passivation layer 96, which may contain, silicon oxide, silicon nitride or a mixture of both, for example.

In a next step, microwires 101 are formed between the light-emitting regions 100₁, 100₂. The microwires 101 have a length h₁ which is greater than the height h₂ of the semiconductor chips. For example, the length h₁ is 2 to 200 μm and the height h₂ is 1 to 20 μm or less, for example, 1 to 10 μm or 1 to 5 μm. The microwires can be applied over the passivation layer 96, for example.

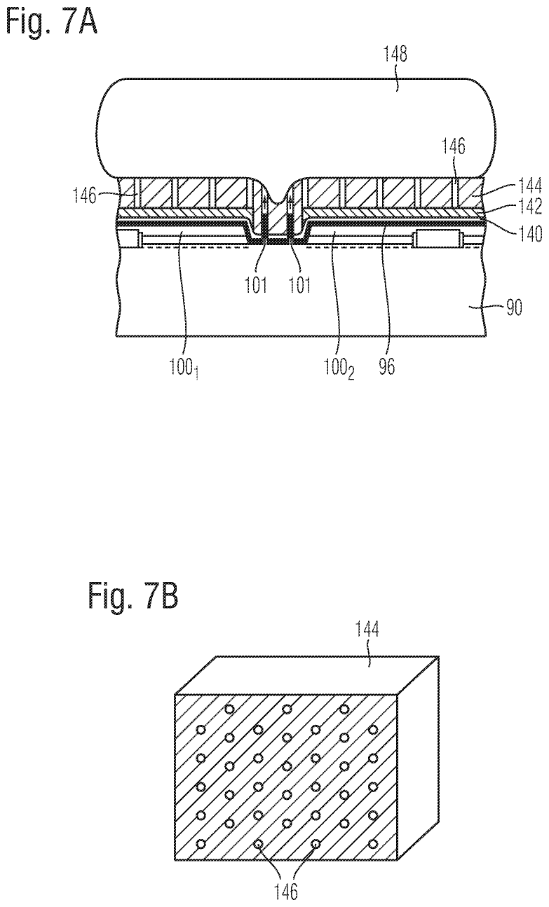

A method for applying the microwires 101 will be described later with reference to FIGS. 7A and 7B. For example, the microwires 101 have a diameter d of 600 to 1500 nm, in particular 0.8 to 1.2 μm. For example, the length h₁ of the microwires can be from 2 to 200 μm. The microwires may contain, for example, a metal such as silver, copper or aluminum, or a suitable compound or alloy, or may be produced from these materials. If appropriate, the microwires may also have a protective layer. For example, the protective layer can contain aluminum oxide (Al₂O₃) if the microwires 101 contain aluminum. For example, the protective layer can be applied by an ALD process (“atomic layer deposition”).

FIG. 2B shows an example of a resulting arrangement. According to embodiments, for example, an optically isolating material 130 can be filled into the spaces between adjacent microwires. The optically isolating material 130 is suitable for reflecting light, for example. In addition or alternatively, the optically isolating material can also absorb light. For example, the optically isolating material 130 may contain a suitable casting material, for example silicone or epoxy resin with metallic particles or light-absorbing additives. Examples of metallic particles are small silver particles/silver flitter. An example of a light-absorbing additive is TiO₂. FIG. 2C shows an example of a resulting cross-sectional view.

The microwires have a high surface energy due to their small diameter. Accordingly, for example, when the spaces between adjacent rows of microwires are filled with a suitable optically isolating material 130, a skin is formed, as described later by reference to FIG. 2E.

According to further embodiments, a converter can then be applied over the light-emitting regions 100₁, 100₂. For example, the converter can be implemented by a converter-containing casting compound, i.e. a resin or polymer compound such as a silicone-based or epoxy resin containing a suitable fluorescent material. For example, as shown in FIG. 2D, different converter materials can be applied over adjacent light-emitting regions 100₁ and 100₂. For example, the first converter-containing casting compound 132 over the first light-emitting region 100₁ may contain a fluorescent which emits light of a first color, for example yellow, while the second converter-containing casting compound 134 over the second light-emitting region 100₂ contains a fluorescent which emits light of a second color, for example green.

In the arrangement shown in FIG. 2D, the microwires 101 prevent a lateral outflow of the first casting compound 132 or the second converter-containing casting compound 134. Furthermore, the arrangement of the microwires between adjacent light-emitting regions 100₁, 100₂ improves the optical separation of the two light-emitting regions 100₁, 100₂. The additional arrangement of the optically isolating material 130 between the adjacent rows of microwires 101 also increases the optical isolation between the two light-emitting regions 100₁, 100₂ further. The microwires thus reduce crosstalk and also act as highly effective limiters for the separating layers.

FIG. 2E shows a schematic plan view of a part of the optoelectronic component with two adjacently arranged rows 102 of microwires 101. For example, the distance f between adjacent microwires 101 is 0.1 μm to 15 μm. The diameter d is approximately 600 to 1500 nm, for example, 0.8 to 1.2 μm. The microwires have a very high surface energy. Accordingly, when the optically isolating material 130 is filled in, given an appropriate choice of the viscosity a skin 131 forms between adjacent microwires 101, and a lateral outflow of the optically isolating material can be prevented. For example, the viscosity of the filling material, for example the optical insulator, can be dimensioned as a function of the diameter and spacing of the microwires in such a way that any lateral outflow is prevented. Conversely, the diameter and/or spacing of the microwires can be dimensioned as a function of the viscosity of the filling material in an analogous way. For example, a viscosity of the optically isolating material can be greater than 10 MPa·s or greater than 100 MPa·s.

FIG. 2F illustrates the situation in a case in which a first casting compound 132 is applied to the left side of the microwire arrangement 102 and a second casting compound 134 is applied to the right side of the microwire arrangement 102. Here also, due to the viscosity of the respective casting compounds 132, 134, the high surface energy of the microwires and the appropriate distance between neighboring microwires, a skin 131 is formed, so that any intermixing of the converter-containing casting compounds or lateral outflow is prevented in each case.

As a result, it is possible to provide a very small distance between adjacent light-emitting regions 100₂, 100₂. If the light-emitting regions 100₂, 100₂ are realized by separate semiconductor chips, the distance can be at least 5 μm or greater than 20 μm. The distance can be less than 100 μm, for example. The distance is measured, as shown in FIG. 2D, between adjacent edges or sides of the light-emitting regions. If the light-emitting regions 100₂, 100₂ refer to different pixels assigned to a semiconductor chip 200, as will be described in relation to FIGS. 9A and 9B, for example, then the lower limit of the distance is determined by the diameter of the microwires. In this case, the distance between different light-emitting regions or pixels can be greater than 0 μm, for example, greater than 2 μm. The distance between different light-emitting regions can be less than 10 μm, for example.

At the same time, different converter materials can be arranged over the individual light-emitting regions. The arrangement shown having light-emitting regions and microwires between the light-emitting regions can also be implemented with converters that are realized in a different way to the converter-containing casting compound described.

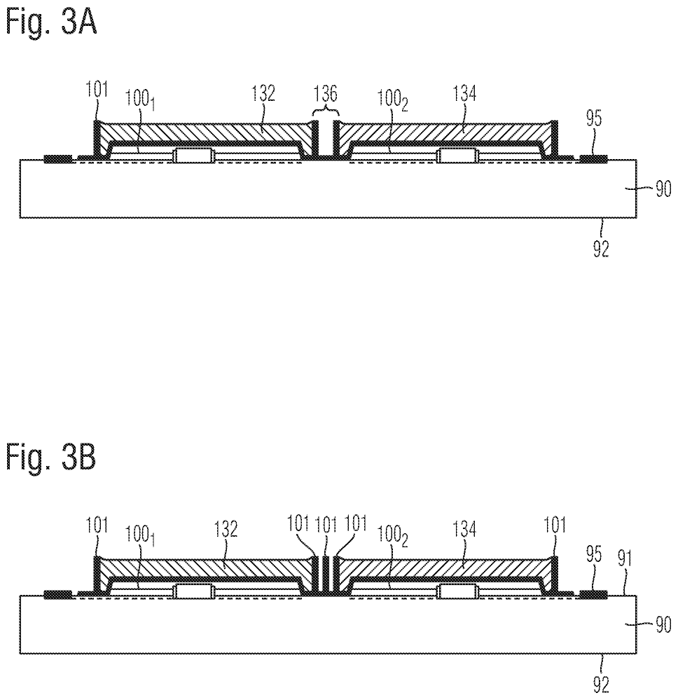

FIGS. 3A and 3B show variations of the optoelectronic component shown in FIG. 2D. As shown in FIG. 3A, for example, the space between adjacent microwire rows 102 might not be filled with an optically isolating material 130. For example, the space between adjacent microwire rows 102 may intentionally not be filled. For example, the intermediate space 136 may be empty or contain no material that is different to, for example, the first or second converter-containing casting compound 132, 134. In the arrangement shown in FIG. 3A, satisfactory optical isolation is ensured by the presence of the adjacently arranged microwire arrangements 102 or microwire rows. Any lateral outflow of the first or second converter-containing casting compound 132, 134 can be prevented due to the high surface energy of the microwires 101. If necessary, for example, the diameter or spacing of the microwires 101 can be selected according to the viscosity of the converter-containing casting compounds.

According to further exemplary embodiments, as shown for example in FIG. 3B, an additional row of microwires can be provided between the rows of microwires arranged between each two light-emitting regions. As a result, three or more microwires may thus be provided between adjacent light-emitting regions 100₁, 100₂.

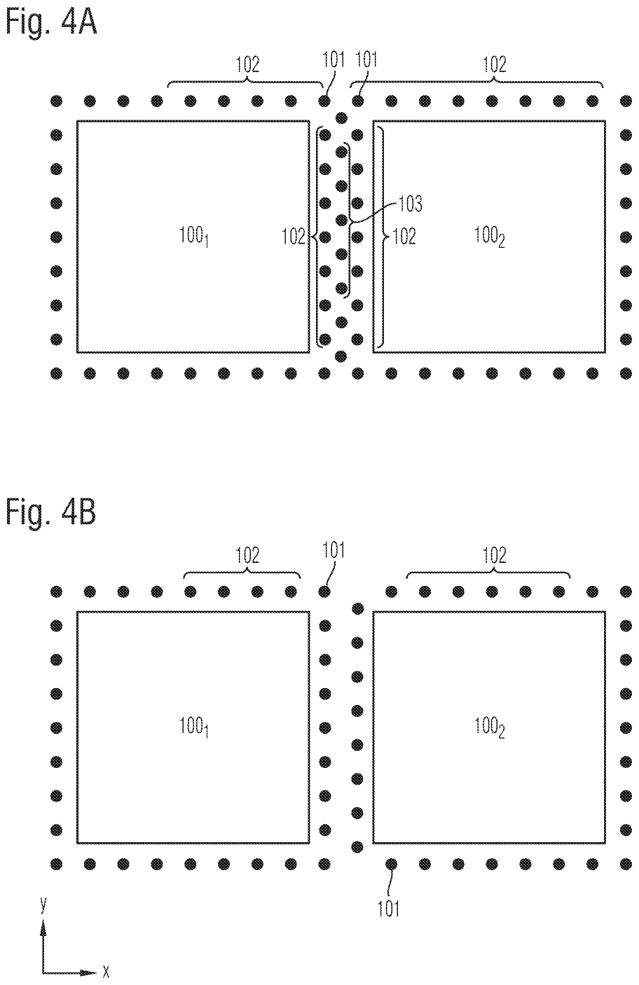

FIG. 4A shows an example of a plan view of a part of the optoelectronic component. The microwire arrangements 102 are arranged in such a manner that they surround a light-emitting region 100₁, 100₂. Furthermore, an additional arrangement 103 is arranged between the microwire row 102, which in each case surrounds the light-emitting regions. This can improve the optical isolation between adjacent light-emitting regions.

According to further embodiments, the individual microwires 101 can be arranged in such a way that, as shown in FIG. 4B, for example, the microwires 101, which are each located between adjacent light-emitting regions 100₁, 100₂, are in a staggered arrangement. More precisely, between the light-emitting regions 100₁, 100₂ shown, the Y positions of the microwires 101 are each selected in such a way that they are offset relative to each other in each case.

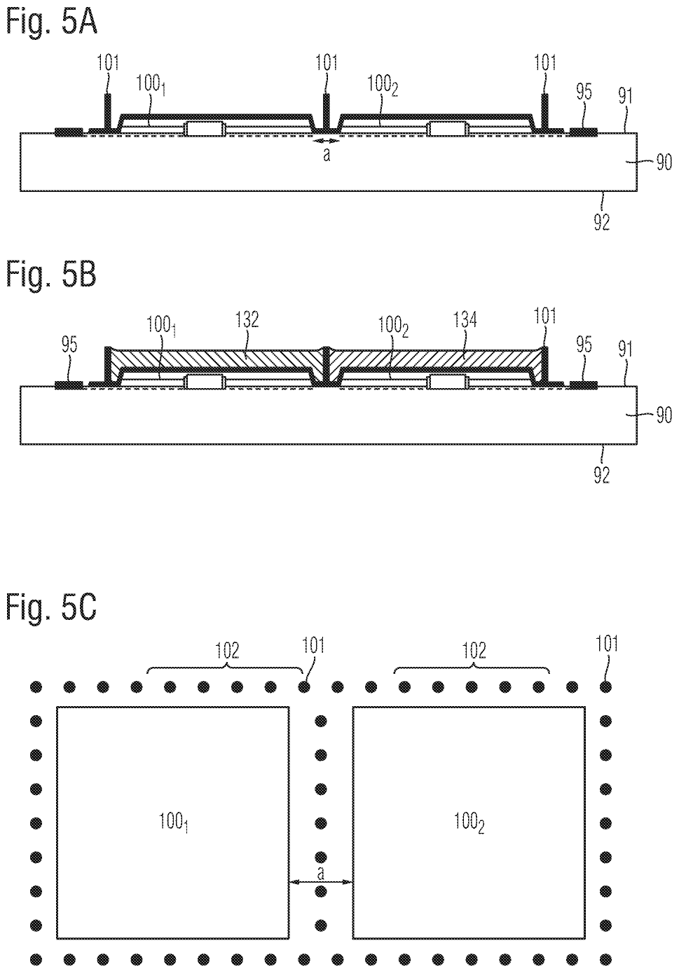

According to some embodiments, which are shown in FIG. 5A for example, only one microwire row or arrangement 102 of microwires 101 is provided between adjacent light-emitting regions 100₁, 100₂. This allows light-emitting regions to be arranged at a smaller distance from each other. Here also, it is possible to apply a first casting compound 132, which contains a first fluorescent, for example, over the light-emitting region 100₁. It is additionally possible to apply a second casting compound 134, which contains a second fluorescent, over the second light-emitting region 100₂.

This is shown, for example, in FIG. 5B. In a similar way to that shown in FIG. 2F, the two converter-containing casting compounds 132, 134 are separated from each other by the high surface energy of the microwires. FIG. 5C shows a plan view of a part of the optoelectronic component in a case in which only one microwire row or arrangement 102 of microwires 101 is arranged between adjacent light-emitting regions 100₁, 100₂.

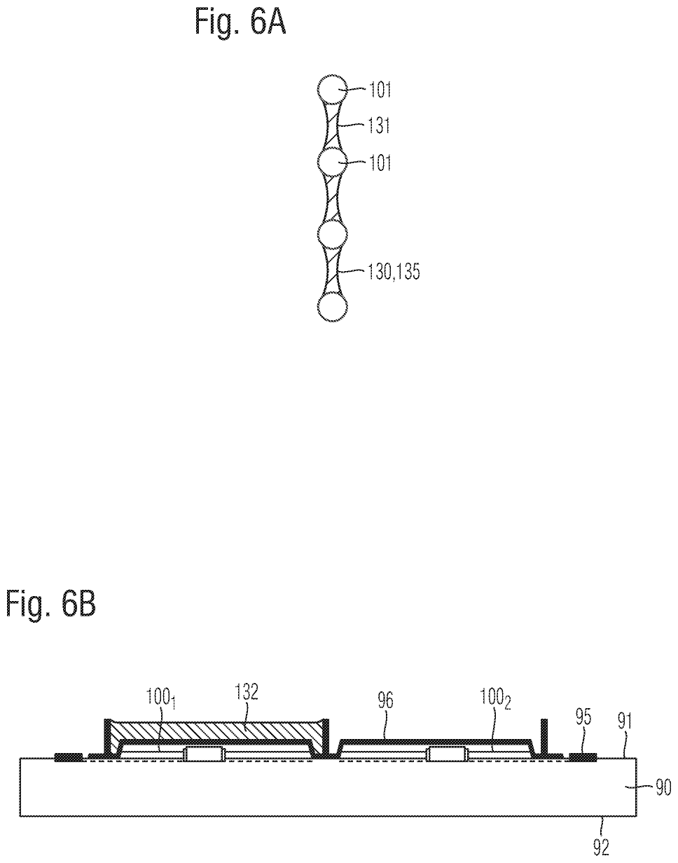

Even if only one row of microwires is present, as illustrated in FIG. 5A or 5B for example, an optically isolating 130 or a casting compound 135 can be applied along a row of microwires, for example, as shown in FIG. 6A. The optically isolating material 130 or the casting compound 135 is applied, for example, by means of a dispenser device in such a way that it fills the space between adjacent microwires 101. Due to the high surface energy of the microwires 101, a skin 131 is again formed here, by means of which the optically isolating material 130 or the casting compound 135 is prevented from flowing out to the side. For example, the viscosity of the optically isolating material 130 or the casting compound 135, the diameter of the microwires 101 and the spacing between the microwires 101 can be selected in relation to each other so as to prevent any lateral outflow of the optically isolating material 130.

Instead of the optically isolating material 130, another material can also be inserted, through which, for example, the converter-containing casting compounds 132, 134 can be separated from each other. According to other embodiments, the optically isolating material 130, the casting compound 135 or another separating material can be introduced by an electrophoretic deposition process (“EPD”—electrophoretic deposition), in which a suitable voltage is applied to the individual microwires. For example, the optically isolating material 130 is deposited on the electrodes, i.e. the microwires. Similarly, the optically isolating material 130 can be formed between adjacent microwires. According to other embodiments it is possible to flood the entire arrangement with the optically isolating material 130 or the casting compound 135 or another separating material, and then wash it out. The material between the neighboring microwires 101 cannot be removed by this process, so that a bridge, as shown in FIG. 6A, for example, is formed between neighboring microwires 101.

The embodiments shown in FIG. 6A can be combined with the embodiments of FIGS. 5A and 5B.

According to embodiments, the optoelectronic component 10 can also be realized in such a way that if only one or even two microwire rows 102 are present between adjacent light-emitting regions 100₁, 100₂, a converter-containing casting compound 132 is introduced over only one of the two light-emitting regions. This is shown, for example, in FIG. 6B. Here, the first converter-containing casting compound is arranged over the light-emitting region 100₁. The light-emitting region 100₂ emits unconverted light. Again, due to the skin formation described in FIG. 6A, a lateral outflow of the converter-containing casting compound 132 is prevented.

FIG. 7A shows a schematic cross-sectional view of a region of the optoelectronic component in the production of the microwires. For example, a seed layer 140 is formed over a surface on which the microwires are to be formed. For example, the seed layer 140 can be arranged directly on the passivation layer 96. A photoresist material 142 is applied over the resulting surface and structured, for example by spinning (spin-coating) or spraying (spray-coating). The photoresist material 142 covers the regions on which no microwires are to be grown and leaves the regions on which the microwires are to be formed uncovered. A structured film or filter film 144 is then placed over the resulting surface. The structured film contains a plastic, for example polyethylene terephthalate, in which a plurality of linear holes 146 or filter pores are arranged. In principle, microwires grow galvanically at the positions of the holes if the seed layer 140 is not covered by the photoresist material 142 at this point. The thickness of the structured film 144 can be 100 to 500 μm, for example. For example, the linear filter pores have a diameter of a few microns.

Then an electrolyte 148 is introduced over the surface of the film 144 in a suitable manner. For example, a pad soaked with the electrolyte 148 can be placed on the surface of the film 144. This method allows microwires, for example, made of a conductive material, to be galvanically grown at positions corresponding to the positions of the holes 146. No growth takes place at locations where the seed layer 140 is covered by the photoresist material 142. FIG. 7B shows a perspective view of an example of a structured film 144. After completion of the procedure, the structured film 144 can be removed, for example by dissolving in a suitable solvent. Examples of the material to be grown by this method include copper, gold, silver, platinum, nickel, and tin. Of course, other methods of forming microwires can also be used.

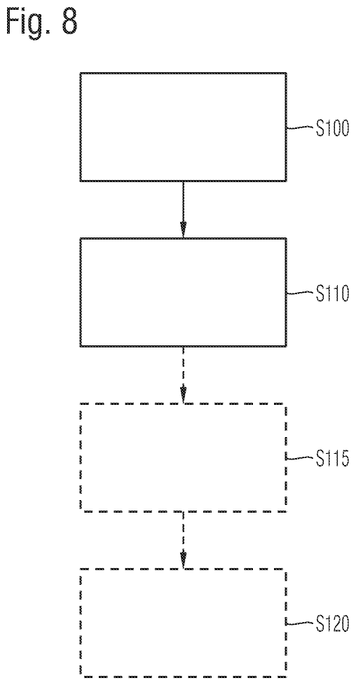

FIG. 8 summarizes a method according to embodiments. A method for producing an optoelectronic component comprises the (S100) arrangement of a plurality of light-emitting regions on a carrier substrate, and the (S110) formation of a plurality of microwires, which are each arranged between individual light-emitting regions. The microwires protrude at right angles relative to a main surface of the carrier substrate. According to embodiments, the process can also comprise (S120) the application of a converter-containing casting compound over one of the light-emitting regions, wherein the converter-containing casting compound is positioned adjacent to the microwire row surrounding the light-emitting region.

According to other embodiments, the method (S115) can further comprise the application of an optically isolating material (130) between adjacent microwire rows (102, 103) or along a microwire row. The application of the optically isolating material can take place, for example, before or after applying the converter-containing casting compound.

FIG. 9A shows a cross-sectional view through a part of an optoelectronic component 10 or a workpiece for producing an optoelectronic component according to other embodiments. A semiconductor chip 200 is arranged on the first main surface 91 of a suitable carrier substrate 90. For example, the semiconductor chip can comprise a first semiconductor layer 110 and a second semiconductor layer 120. The structure of the semiconductor chip 200 and its arrangement on the carrier substrate 90 may be similar to that described above, for example, by reference to FIG. 2A. According to the embodiments shown in FIG. 9A, the microwires 101 are arranged over the semiconductor chip 200. For example, the microwires 101 can be arranged on the passivation layer 96. The structure, arrangement and production of the microwires may be similar to those described by reference to the preceding figures. For example, different converter-containing casting compounds 132, 134 can each be arranged between the microwire rows of microwires 101. According to the embodiments shown in FIG. 9A, microwires are arranged between the individual light-emitting regions 100₁, 100₂, 100₃, 100₄ here also. The microwires protrude relative to a main surface 91 of the carrier substrate 90. According to FIG. 9A, the individual light-emitting regions correspond in each case to pixels, a plurality of which are assigned to each semiconductor chip 200.

FIG. 9B shows a cross-sectional view of an optoelectronic component 10 or a workpiece for producing an optoelectronic component according to other embodiments. Here, a portion of the microwires 101 is arranged between neighboring semiconductor chips 200. Another portion of the microwires is arranged above the respective semiconductor chips 101. The microwires 101 can be arranged over the passivation layer 96, for example. Other components of the optoelectronic component have been described by reference to FIG. 2B or 5A, for example. For example, different converter-containing casting compounds 132, 134 can each be arranged between the microwire rows of microwires 101, in a similar way to the drawing in FIG. 9A.

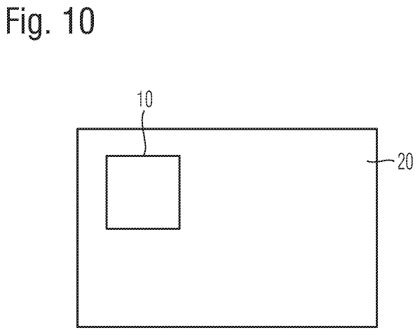

FIG. 10 shows an electrical device 20 which contains the optoelectronic component 10 described. For example, the electrical device 20 can be a car headlamp in which individual light-emitting regions 100₁, 100₂, . . . 100n can be switched on or off as required. According to other examples, the electrical device 20 can be a general lighting device in which specific light-emitting regions 100 can be selectively switched on or off as required. Depending on the fluorescent material of the particular converter layer 132, 134 adjacent to the light-emitting region that is switched on or off, different colors of the emitted light, or different color temperatures (warm white, cold white), can be set.

The fact that the optoelectronic component 10 has vertically protruding microwires in accordance with the embodiments provides improved optical separation and can reduce crosstalk between adjacent pixels or light-emitting regions. As a result, a high contrast can be achieved. In addition, a better color purity can be achieved in different converter regions. In addition, the microwires represent an effective mechanical barrier by means of which the applied layers are delimited. As a result, among other things, the spacing of the light-emitting regions can be reduced, thus allowing an optoelectronic component 10 with a more compact size to be achieved. As can be seen from the detailed description of the embodiments, the principle described—that adjacent light-emitting regions are separated from each other by microwires—can be realized regardless of the exact type of photon generation used.

Although specific embodiments have been illustrated and described in this document, persons skilled in the art will recognize that the specific embodiments shown and described can be replaced by a plurality of alternative and/or equivalent designs without departing from the scope of protection of the invention. The application is intended to include any modifications or variations of the specific embodiments discussed herein. Therefore, the invention is limited only by the claims and their equivalents.

### LIST OF REFERENCE SIGNS

10 optoelectronic component
20 electrical device
90 carrier substrate
91 first main surface of the carrier substrate
92 second main surface of the carrier substrate
95 contact element
96 clear casting compound
100₁ . . . 100ₙ light-emitting region
101 microwire
102 microwire arrangement
103 additional microwire arrangement
110 first semiconductor layer
115 first contact region
116 electrical connection
120 second semiconductor layer
125 second contact region
126 via-contact
127 insulating material
130 optically isolating material
131 skin
132 first converter-containing casting compound
134 second converter-containing casting compound
135 casting material
136 intermediate space
140 seed layer
142 photoresist material
144 structured film
146 holes
148 electrolyte
200 semiconductor chip

1. An optoelectronic component comprising:
a plurality of light-emitting regions arranged on a carrier substrate; and
microwires that project relative to a main surface of the carrier substrate; wherein a plurality of microwires is arranged between each pair of adjacent light-emitting regions; and wherein the light-emitting regions are each surrounded by rows of microwires.

2. The optoelectronic component as claimed in claim 1, wherein the microwires each have a diameter of 600 nm to 1500 nm and a spacing of 0.1 μm to 15 μm.

3. The optoelectronic component as claimed in claim 1, wherein the microwires comprise metallic material.

4. The optoelectronic component as claimed in claim 1, wherein the microwires are arranged along at least one line to form a row of microwires.

5. (canceled)

6. The optoelectronic component as claimed in claim 1, wherein the converter-containing casting compound is adjacent to the microwire row that surrounds the light-emitting region and is bounded by the microwire row.

7. The optoelectronic component as claimed in claim 15, wherein different converter-containing casting compounds are present over adjacent light-emitting regions.

8. The optoelectronic component as claimed in claim 4, further comprising a space is arranged in each case between the microwire rows of adjacent light-emitting regions.

9. The optoelectronic component as claimed in claim 8, wherein the space is filled with optically isolating material.

10. The optoelectronic component as claimed in claim 9, further comprising an arrangement of additional microwires in the space.

11. The optoelectronic component as claimed in claim 1, wherein exactly one microwire row is arranged in each case between adjacent light-emitting regions.

12. The optoelectronic component as claimed in claim 11, further comprising a casting material arranged along the microwire row.

13. (canceled)

14. The optoelectronic component as claimed in claim 1, wherein the microwires are each insulated from electrical components of the optoelectronic component.

15. A method for producing an optoelectronic component, wherein the method comprises:
arranging a plurality of light-emitting regions on a carrier substrate; and
forming microwires that project vertically relative to a main surface of the carrier substrate; wherein a plurality of microwires is arranged between each pair of adjacent light-emitting regions; and wherein the light-emitting regions are each surrounded by rows of microwires.

16. The method as claimed in claim 15, wherein the microwires each have a diameter ranging from 600 nm to 1500 nm and a spacing ranging from 0.1 μm to 15 μm.

17. The method as claimed in claim 15 or 16, further comprising forming the microwires by electroplating.

18. The method as claimed in claim 17, wherein the microwires are formed using a structured plastic film.

19. The method as claimed in claim 15, further comprising arranging the microwires along lines to form a row of microwires.

20. The method as claimed in claim 19, further comprising applying a converter-containing casting compound over one of the light-emitting regions, wherein the converter-containing casting compound is adjacent to the microwire row which surrounds the light-emitting region and is bounded by the microwire row.

21. An electrical device having the optoelectronic component as claimed in claim 1.

22. The electrical device as claimed in claim 21, wherein the electrical device is a motor vehicle headlamp or a general lighting device.
